(19) United States
(12) Patent Application Publication
(10) Pub. No.: US 2025/0204199 A1
(43) Pub. Date: Jun. 19, 2025

(54) DISPLAY PANEL AND DISPLAY APPARATUS

(71) Applicant: Wuhan Tianma MicroElectronics Co, Ltd Shanghai Branch, Shanghai (CN)

(72) Inventor: Nana XIONG, Shanghai (CN)

(21) Appl. No.: 18/663,968

(22) Filed: May 14, 2024

(30) Foreign Application Priority Data
Dec. 18, 2023 (CN) 202311746520.2

(51) Int. Cl. H10K 59/65; H10K 59/121

(52) U.S. Cl. CPC H10K 59/65; H10K 59/1213

(57) ABSTRACT

The present disclosure includes a display panel and a display apparatus. The display panel includes a first display region and a second display region, where the second display region at least partially surrounds the first display region, and a transmittance of at least a part of the first display region is greater than a transmittance of the second display region; and further includes a plurality of photosensitive units, where the plurality of photosensitive units includes a plurality of fingerprint recognition units and a plurality of first photosensitive units; the plurality of first photosensitive units is at the first display region; the plurality of fingerprint recognition units is at the second display region; and the plurality of first photosensitive units includes a plurality of color temperature sensors and/or a plurality of ambient light sensors.

### CROSS-REFERENCE TO RELATED APPLICATION

The present disclosure claims the priority of Chinese Patent Application No. 202311746520.2, filed on Dec. 18, 2023, the content of which is incorporated herein by reference in its entirety.

### TECHNICAL FIELD

The present disclosure generally relates to the field of display technology and, more particularly, relates to a display panel and a display apparatus.

### BACKGROUND

From the CRT (cathode ray tube) era to the LCD (liquid crystal display) era, and to the OLED (organic light-emitting diode) era and the light-emitting diode (LED) era, the display industry has changed rapidly after decades of development. The display technology has been used in display apparatuses from mobile phones, tablets, TVs and PCs to smart wearable devices, VRs, car displays, and other electronic devices.

With the development of the display technology, users have higher requirement for diversified functions of display products. Functions such as fingerprint recognition and ambient light recognition and the like have become essential functions of the display products. However, when sensing units with these functions are integrated inside the display products, the pixel densities of the display products may be greatly affected.

### SUMMARY

One aspect of the present disclosure provides a display panel. The display panel includes a first display region and a second display region, where the second display region at least partially surrounds the first display region, and a transmittance of at least a part of the first display region is greater than a transmittance of the second display region; and further includes a plurality of photosensitive units, where the plurality of photosensitive units includes a plurality of fingerprint recognition units and a plurality of first photosensitive units; the plurality of first photosensitive units is at the first display region; the plurality of fingerprint recognition units is at the second display region; and the plurality of first photosensitive units includes a plurality of color temperature sensors and/or a plurality of ambient light sensors.

Another aspect of the present disclosure provides a display apparatus including a display panel. The display panel includes a first display region and a second display region, where the second display region at least partially surrounds the first display region, and a transmittance of at least a part of the first display region is greater than a transmittance of the second display region; and further includes a plurality of photosensitive units, where the plurality of photosensitive units includes a plurality of fingerprint recognition units and a plurality of first photosensitive units; the plurality of first photosensitive units is at the first display region; the plurality of fingerprint recognition units is at the second display region; and the plurality of first photosensitive units includes a plurality of color temperature sensors and/or a plurality of ambient light sensors.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

FIG. 1 illustrates a structural schematic of a display panel according to various embodiments of the present disclosure.

FIG. 2 illustrates a local enlarged view of a first display region and a part of a second display region surrounding the first display region in FIG. 1.

FIG. 3 illustrates an arrangement schematic of sub-pixels in a first display region and a second display region in FIG. 1.

FIG. 4 illustrates another local enlarged view of a first display region and a part of a second display region surrounding the first display region in FIG. 1.

FIG. 5 illustrates a film layer schematic along a BB direction in FIG. 4.

FIG. 6 illustrates another local enlarged view of a first display region and a part of a second display region surrounding the first display region in FIG. 1.

FIG. 7 illustrates another local enlarged view of a first display region and a part of a second display region surrounding the first display region in FIG. 1.

FIG. 8 illustrates another film layer schematic along a BB direction in FIG. 4.

FIG. 9 illustrates another local enlarged view of a first display region and a part of a second display region surrounding the first display region in FIG. 1.

FIG. 10 illustrates another film layer schematic along a BB direction in FIG. 4.

FIG. 11 illustrates another film layer schematic along a BB direction in FIG. 4.

FIG. 12 illustrates a detailed film layer schematic of a display panel according to various embodiments of the present disclosure.

FIG. 13 illustrates another detailed film layer schematic of a display panel according to various embodiments of the present disclosure.

FIG. 14 illustrates a structural schematic of a display apparatus according to various embodiments of the present disclosure.

### DETAILED DESCRIPTION

Various exemplary embodiments of the present disclosure are described in detail with reference to accompanying drawings. It should be noted that unless stated otherwise, relative arrangement of assemblies and steps, numerical expressions and values described in those embodiments may not limit the scope of the present disclosure.

Following description of at least one exemplary embodiment may be merely illustrative and may not be configured to limit the present disclosure and its application or use.

The technologies, methods and apparatuses known to those skilled in the art may not be discussed in detail, but where appropriate, the technologies, methods and apparatuses should be considered as a part of the present disclosure.

In all examples shown and discussed herein, any specific value should be interpreted as merely exemplary, rather than as a limitation. Therefore, other examples in exemplary embodiment may have different values.

It is apparent to those skilled in the art that various modifications and variations may be made in the present disclosure without departing from the spirit or scope of the present disclosure. Therefore, the present disclosure is intended to cover modifications and variations of the present disclosure falling within the scope of corresponding claims (technical solutions to be protected) and their equivalents. It should be noted that, implementation manners provided in embodiment of the present disclosure may be combined with each other if there is no contradiction.

It should be noted that similar reference numerals and letters are configured to indicate similar items in following drawings. Therefore, once an item is defined in one drawing, it does not need to be further discussed in subsequent drawings.

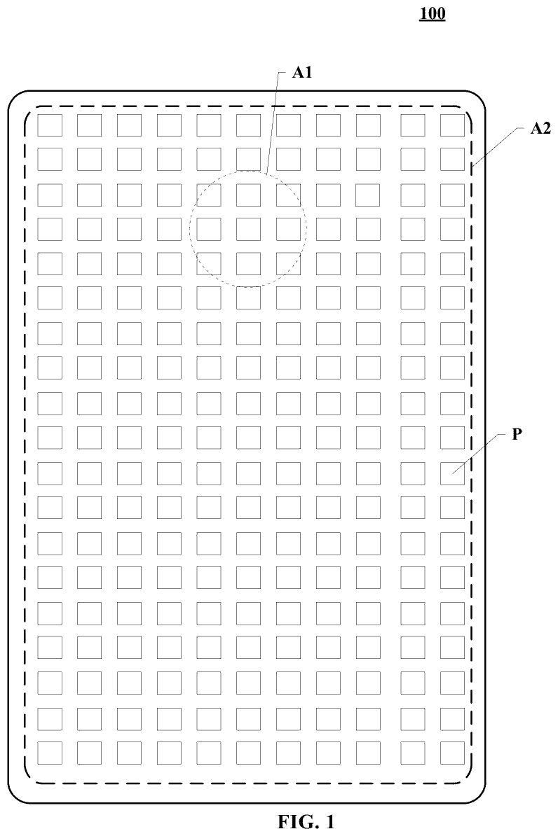

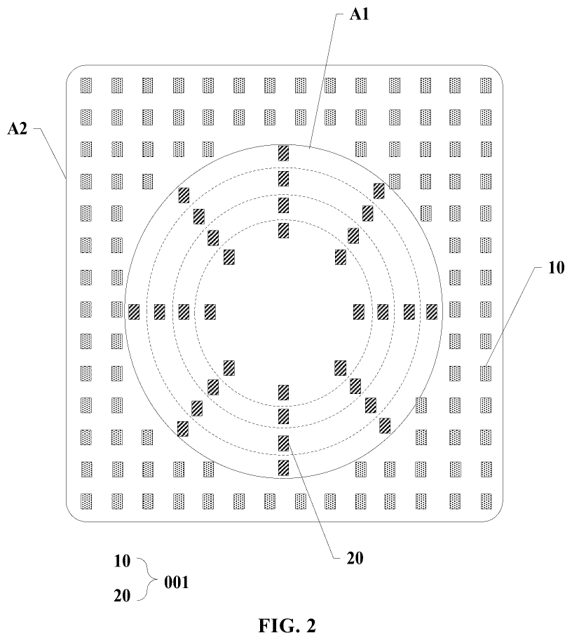

FIG. 1 illustrates a structural schematic of a display panel according to various embodiments of the present disclosure; and FIG. 2 illustrates a local enlarged view of a first display region and a part of a second display region surrounding the first display region in FIG. 1. Referring to FIGS. 1-2, a display panel 100 provided by embodiments of the present disclosure may include a first display region A1 and a second display region A2. The second display region A2 may at least partially surround the first display region A1, and the transmittance of at least a part of the first display region A1 may be greater than the transmittance of the second display region A2.

The display panel may further include a photosensitive unit 001. The photosensitive unit 001 may include a fingerprint recognition unit 10 and a first photosensitive unit 20. The first photosensitive unit 20 may be at the first display region A1, and the fingerprint recognition unit 10 may be at the second display region A2. The first photosensitive unit 20 may include a color temperature sensor and/or an ambient light sensor.

It should be noted that the display panel with a rectangular structure is taken as an example to illustrate the display panel in one embodiment of FIG. 1, which may not limit specific structure of the display panel of the present disclosure. In some other embodiments of the present disclosure, the shapes of the display panel may also be embodied as a rounded rectangle, a circle, an ellipse, or other structures including arc edges, which may not be limited in the present disclosure. FIG. 1 only illustrates a relative position of the first display region A1 on the display panel. In some other embodiments of the present disclosure, the first display region A1 may also be configured at other positions of the display panel, and the shape of the first display region A1 may also be configured according to actual situation. The circle in FIG. 1 may be only exemplary. For example, the first display region A1 may also be configured in a square, a racetrack shape or the like. In addition, the size of the first display region A1 may also be flexibly configured according to actual need.

In one embodiment of FIG. 1, a pixel arrangement in the first display region A1 and the second display region A2 is illustrated, and the photosensitive units are not illustrated. In one embodiment of FIG. 2, the photosensitive units 001 in the first display region A1 and a part of the second display region A2 are illustrated, and the pixels are not illustrated. The sub-pixels P may be disposed in both the first display region A1 and the second display region A2. The pixel arrangement in FIG. 1 may be only exemplary, and may not limit the quantity, the shape and the arrangement structure of the sub-pixels P in the first display region A1 and the second display region A2 in the display panel. In the display panel provided by embodiments of the present disclosure, the second display A2 may be at least partially disposed around the first display region A1. Optionally, the second display region A2 may surround the first display region A1 as an example for illustration. In some other embodiments of the present disclosure, the second display region A2 may also partially surround the first display region A1, which may not be limited in the present disclosure. Optionally, the first display region A1 may be configured to dispose a camera to realize the image-capturing function of the displayed product. The sub-pixels P may be disposed in both the first display region A1 and the second display region A2. In the display stage, the sub-pixels P in the second display region A2 and the first display region A1 may all perform display function. In the image-capturing stage, the first display region A1 may be configured as a light-transmitting region. At this point, the sub-pixels of the first display region A1 may not emit light, and the first display region A1 may be configured as the light-transmitting region to implement the image-capturing function. In embodiments of the present disclosure, the first display region A1 that performs the photosensitive function may be integrated into the display region, which may be beneficial for reducing the space of the non-display region of the display panel, thereby being beneficial for realizing narrow frame or frameless design of the display panel and improving overall screen-to-body ratio of the display panel.

In embodiments of the present disclosure, the fingerprint recognition unit 10 and the first photosensitive unit 20 may be disposed in the display panel. The first photosensitive unit 20 may include a color temperature sensor or an ambient light sensor or may include both a color temperature sensor and an ambient light sensor. In such way, the fingerprint identification unit 10 may be configured to realize the fingerprint identification function of the display panel, and the first photosensitive unit 20 may be configured to realize the ambient light sensing function of the display panel.

In the existing technology, when the fingerprint recognition unit and the ambient light sensing unit are both disposed in the display product, a feasible manner may be to integrate the fingerprint recognition unit and the ambient light sensing unit with the display panel in a plug-in manner. Such structure may result in a relatively large display product thickness, which may not be beneficial for thinning requirement. Another possible manner may be to embed both the fingerprint recognition unit and the ambient light sensing unit inside the display panel to reduce the thickness of the display product and meet the thinning requirement. Since both the fingerprint recognition unit and the ambient light sensing unit have corresponding sensors and driving circuits which occupy display panel space, there is a need to avoid the influence of the introduction of these units on the PPI (pixels in inch) of the display panel.

In order to solve above technical problems, when the fingerprint recognition unit 10 and the first photosensitive unit 20 are disposed in the display panel, the fingerprint recognition unit 10 may be disposed in the second display region A2 with a relatively large area; the first photosensitive unit 20 may be disposed in the first display region A1 with a relatively small region; and the fingerprint recognition unit 10 and the first photosensitive unit 20 may not be overlapped in the disposing space, thereby being beneficial for avoiding the problem of reduced PPI caused by space squeezed when the fingerprint recognition unit 10 and the first photosensitive unit 20 are overlapped in the disposing space. Therefore, while realizing fingerprint recognition and ambient light sensing simultaneously, it is also beneficial for improving the PPI of the display panel. In addition, when the fingerprint recognition unit 10 is disposed in the first display region A1 in embodiments of the present disclosure, the area of the first display region A1 may be relatively large, which may be beneficial for realizing full-screen fingerprint recognition and meeting full-screen fingerprint recognition need of users. Since the first photosensitive unit 20 only needs a relatively small region to install corresponding sensors to realize the ambient light sensing function, the first photosensitive unit 20 may be disposed in the first display region A1 to meet the region size requirement for ambient light sensing without being overlapped with the fingerprint recognition unit 10 in the second display region A2.

Optionally, the display panel provided in embodiments of the present disclosure may be a display panel using organic light-emitting diode (OLED) display technology. The basic structure of the light-emitting functional layer of the OLED display panel may include an anode, a light-emitting layer and a cathode. When the power supply supplies an appropriate voltage, the holes in the anode and the electrons in the cathode may be combined in the light-emitting material layer to produce bright light. Compared with thin-film field-effect transistor liquid crystal displays, the OLED display apparatuses may have the characteristics of high visibility and high brightness and may be more power-saving, lightweight, and thin. Obviously, in some other embodiments of the present disclosure, the display panel may also be a display panel using inorganic light-emitting diode display technology, such as a Micro LED display panel, a Mini LED display panel or the like.

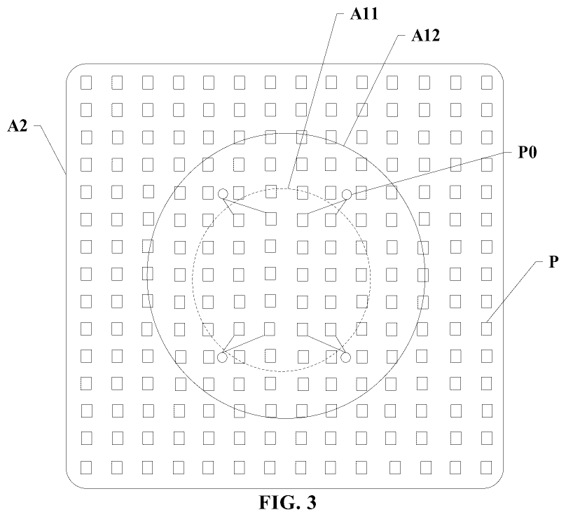

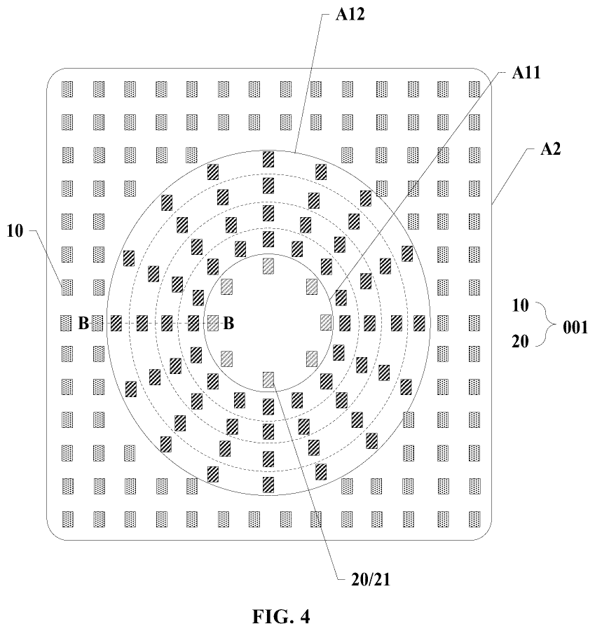

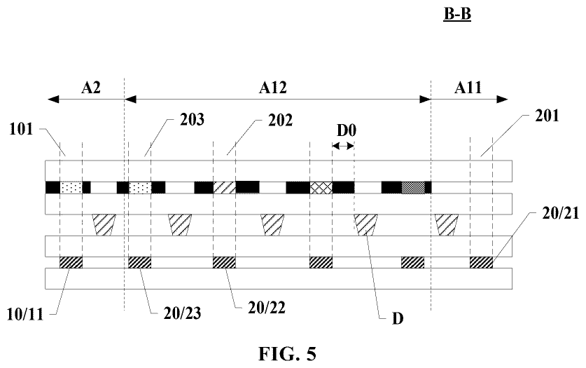

FIG. 3 illustrates an arrangement schematic of sub-pixels in the first display region A1 and the second display region A2 in FIG. 1. The photosensitive units are not shown in FIG. 3. FIG. 4 illustrates another local enlarged view of the first display region A1 and a part of the second display region A2 surrounding the first display region A1 in FIG. 1. The difference between FIG. 2 and FIG. 4 may be that the arrangement density of the first photosensitive units in the first display region A1 may be different. FIG. 5 illustrates a film layer schematic along a BB direction in FIG. 4. It should be noted that FIG. 4 only illustrates an arrangement manner of the photosensitive units in the first display region A1, which not limit the quantity and the arrangement manner of the photosensitive units actually included in the first display region A1. FIG. 5 only illustrates relative positional relationship between a photosensitive channel, a sensor and a light-emitting element and does not show detailed film structure of the display panel.

Referring to FIGS. 3-5, in an optional implementation manner of the present disclosure, the first display region A1 may include a first region A11 and a transition region A12; the transition region A12 may be between the first region A11 and the second display region A2; the transmittance of the first region A11 may be greater than the transmittance of the transition region A12; the first photosensitive unit 20 may include a first sensor 21 and a first photosensitive channel 201; along the direction perpendicular to the plane of the display panel, the first photosensitive channel 201 may be overlapped with the first sensor 21, and the first photosensitive channel 201 may be on the side of the first sensor 21 facing toward the light-exiting surface of the display panel; the first photosensitive channel 201 may be configured to transmit full-band light; and the first sensor 21 and the first photosensitive channel 201 may be at the first region A11.

Referring to FIG. 3, when a camera is disposed in the display product to implement the image-capturing function, the first region A11 in the first display region A1 may be regarded as a region corresponding to the camera, and the camera may sense light through the first region A11 when image-capturing is performed. The region between the second display region A2 and the first region A11 may be the transition region A12. The transmittance of the first region A11 in the first display region A1 may be greater than the transmittance of the transition region A12. The first region A11 and the transition region A12 in the first display region A1 may be both disposed with the sub-pixels P; and each sub-pixel P may have a corresponding pixel driving circuit P0 connected to each sub-pixel P. The pixel driving circuit P0 connected to the sub-pixel P in the first region A11 may be disposed in the transition region A12. That is, the pixel driving circuit P0 may be not disposed in the first region A11, which may be beneficial for improving the transmittance of the first region A11, increasing the light sensitivity of the display panel in the image-capturing stage and further improving the image-capturing effect of the display panel. It should be noted that the first sensor 21 mentioned in one embodiment may be embodied as an ambient light sensor or a color temperature sensor. It should also be noted that FIG. 3 only illustrates the pixel driving circuits P0 connected to a part of the sub-pixels P in the first region A11, and does not show the pixel driving circuits P0 corresponding to all sub-pixels P. In fact, each sub-pixel P may have a corresponding pixel driving circuit P0 connected to each sub-pixel P. In addition, FIG. 3 illustrates a solution that two sub-pixels P in the first region A11 may be connected to a same pixel driving circuit P0, which may not limit corresponding relationship between the quantity of the sub-pixels P and the pixel driving circuits P0. In some other embodiments of the present disclosure, the sub-pixels P in the first region A11 may also be electrically connected to the pixel driving circuits P0 in a one-to-one correspondence.

Referring to FIGS. 4-5, the first photosensitive unit 20 provided by embodiments of the present disclosure may be disposed in the first display region A1; the first photosensitive unit 20 may include the first sensor 21 and the first photosensitive channel 201; the ambient light may be transmitted to the first sensor 21 through the first photosensitive channel 201; and the photosensitive function may be implemented through the first sensor 21. The first photosensitive channel 201 may be configured to transmit full-band light, and the first sensor 21 may be configured to sense the full-band light. In order to improve the transmittance of the first region A11, structures including a light-blocking matrix, a color resist and the like in the first region A11 may be removed to allow full range of ambient light to be transmitted to the camera during the camera image-capturing process. In one embodiment, when the first photosensitive channel 201 and the first sensor 21 are disposed in the first region A11, since the first region A11 allows the full-band light to pass through, there is no need to perform special treatment on the film structure of the first region A11 to meet the transmission requirement of the full-band light. The characteristic of the first region A11 that allows the full-band light to pass through may be reasonably utilized, thereby being beneficial for simplifying the film structure of the first region A11 when the first sensor 21 is disposed in the first region A11. In the first region A11, the first photosensitive channel 201 may be on the side of the first sensor 21 facing toward the light-exiting surface of the display panel. The full-band light in the ambient light may be transmitted to the first sensor 21 through the first photosensitive channel 201 to realize the sensing function of the full-band ambient light. The first photosensitive channel 201 may allow the full-band light to pass through, and the first region A11 itself may allow the full-band light to pass through. Therefore, the region in the first region A11 where the first sensor 21 faces the light-exiting surface of the display panel may be regarded as the first photosensitive channel 201.

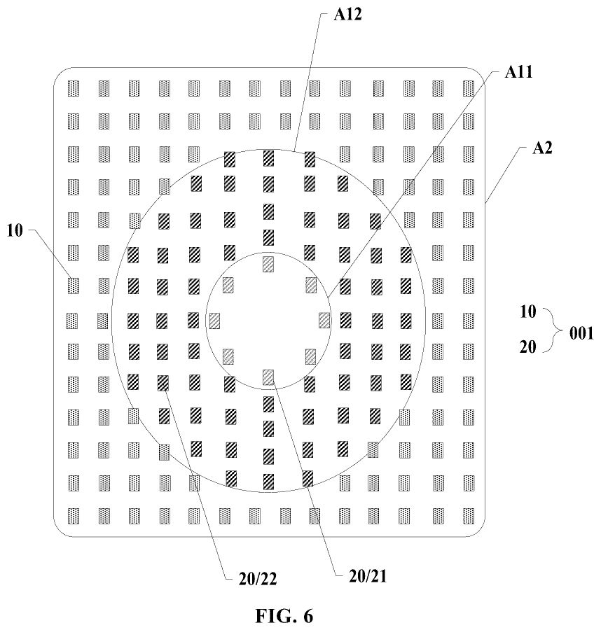

It should be noted that the sensors 21/22 in the first photosensitive units 20 may be arranged in a circle as an example for illustration in one embodiment of FIG. 4, but actual arrangement structures of the sensors may not be limited. In fact, the sensors in the first photosensitive units 20 may also have other arrangement structures. For example, referring to FIG. 6, FIG. 6 illustrates another local enlarged view of the first display region A1 and a part of the second display region A2 surrounding the first display region A1 in FIG. 1. In one embodiment, it describes a solution that the sensors 21/22 in the first photosensitive units 20 are arranged in an array along the row direction and the column direction. It should be noted that the quantity of sensors provided in the first display region A1 in FIG. 6 may be only exemplary, which may not limit the quantity of sensors actually included in the first display region A1.

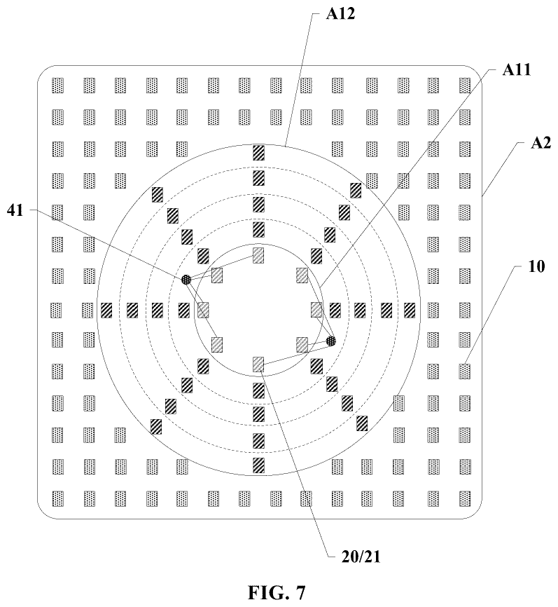

FIG. 7 illustrates another local enlarged view of the first display region A1 and a part of the second display region A2 surrounding the first display region A1 in FIG. 1. In addition to the sensors, driving circuits connected to the sensors may be further shown in one embodiment.

Referring to FIG. 7, in an optional implementation manner of the present disclosure, the first photosensitive unit 20 may further include the first driving circuit 41 connected to the first sensor 21, and the first driving circuit 41 may be in the transition region A12. When the first driving circuit 41 connected to the first sensor 21 in the first region A11 is disposed in the transition region A12, the first driving circuit 41 may not occupy the space of the first region A11, which may be beneficial for preventing the first driving circuit 41 from affecting the transmittance of the first region A11.

It should be noted that FIG. 7 only illustrates the position of the first driving circuit 41 and does not show specific structure of the first driving circuit 41. Specific structure of the first driving circuit 41 may refer to the structure of the driving circuit corresponding to the ambient light sensing sensor in the existing technology, which may not be limited in the present disclosure.

Referring to FIG. 7, in an optional implementation manner of the present disclosure, a same first driving circuit 41 may be connected to a quantity N of first sensors 21, where N≥4.

When at least four first sensors 21 are connected to the same driving circuit, the brightness signals sensed by all first sensors 21 connected to the same first driving circuit 41 may be transmitted to the first driving circuit 41; and the signals may be read through the same first driving circuit 41, thereby realizing the identification of the full-band light brightness in the ambient light. Such design manner may be beneficial for reducing the quantity of first driving circuits 41 actually included in the display panel and preventing a large quantity of first driving circuits 41 from affecting the PPI of the display product. It should be noted that FIG. 7 only illustrates that the first region A11 may include 8 first sensors 21 and every four sensors may be connected to one first driving circuit 41, which may not limit the quantity of first sensors 21 actually included in the first region A11. In fact, the first region A11 may include more than eight first sensors 21, and the quantity of first sensors 21 connected to the same first driving circuit 41 may also be more than four.

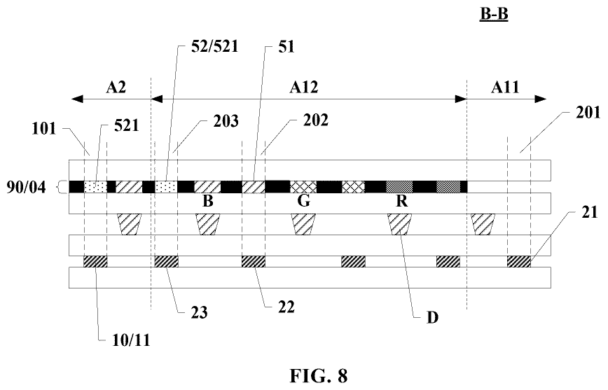

The first photosensitive unit 20 may be configured to sense ambient light. In order to achieve omnidirectional sensing of ambient light, in addition to the first sensor 21 sensing the full-band light, a sensor that can sense a single color of light may also be further disposed. Referring to FIG. 8, in an optional implementation manner of the present disclosure, the first photosensitive unit 20 may also include the second sensor 22 and the second photosensitive channel 202. Along the direction perpendicular to the plane of the display panel, the second photosensitive channel 202 may be overlapped with the second sensor 22, and the second photosensitive channel 202 may be on the side of the second sensor 22 facing toward the light-exiting surface of the display panel. The second photosensitive channel 202 may be configured to transmit red light, green light or blue light; and the second sensor 22 and the second photosensitive channel 202 may be at the transition region A12. FIG. 8 illustrates another film layer schematic along the BB direction in FIG. 4. The difference between FIG. 5 and FIG. 8 is that a filter film may be disposed directly above the light-emitting element D in FIG. 8.

In one embodiment, it describes a solution that the second sensor 22 and the second photosensitive channel 202 in the first photosensitive unit 20 may be disposed in the transition region A12. The second photosensitive channel 202 may be configured to transmit light of a single color, for example, red light, green light or blue light to corresponding second sensor 22, thereby achieving sensing of red light, blue light or filtered light in the ambient light.

The display panel provided by the present disclosure may be the OLED display panel as an example for illustration. In order to reduce reflection, a feasible manner may be to dispose a filter layer 04 (a color film layer 90) on the side of the light-emitting element D facing toward the light-exiting surface of the display panel. The filter layer 04 may be disposed with a filter film and a light-blocking matrix. In the second display region A2 and the transition region A12, a filter film with same color as the light-emitting element D (such as a red color resist R, a green color resist G or a blue color resist B) may be disposed directly above the light-emitting element D. In the first region A11, the filter film and the light-blocking matrix corresponding to the color filter layer 90 may be removed to increase the transmittance of the first region A11, such that the first region A11 may allow the full-band light to pass through. In the above-mentioned embodiments, when the first sensor 21 and the first photosensitive channel 201 are disposed in the first region A11, the first region A11 may desirably meet the full-band light sensing requirement of the first sensor 21 and the first photosensitive channel 201. In one embodiment, when the second sensor 22 and the second photosensitive channel 202 are disposed in the transition region A12, the color filter layer 90 may be reused to form the filter film in the second photosensitive channel 202. The fabrication of the filter film in the second photosensitive channel 202 may be completed while fabricating the filter film on the color filter layer 90, thereby simplifying the fabrication process when the second sensor 22 and the second photosensitive channel 202 are disposed in the display panel.

Referring to FIG. 8, in an optional implementation manner of the present disclosure, the display panel may include a plurality of light-emitting elements D disposed in the first display region A1 and the second display region A2; and along the direction perpendicular to the plane of the display panel, the second photosensitive channel 202 may not be overlapped with the light-emitting element D.

When the second sensor 22 and corresponding second photosensitive channel 202 are disposed in the display panel, along the direction perpendicular to the plane of the display panel, the second sensor 22 may be overlapped with corresponding second photosensitive channel 202, and the second photosensitive channel 202 may not be overlapped with the light-emitting element D, which may be beneficial for preventing the light emitted from the light-emitting element D from entering the photosensitive channel to cause false recognition by the second sensor 22 and avoiding the problem of display color shift caused by the light emitted from the light-emitting element D from the second photosensitive channel 202 to the light-exiting surface of the display panel.

It should be noted that, in one embodiment shown in FIG. 8, it only illustrates a schematic diagram of relative positions of a part of the second photosensitive channel 202, corresponding second sensor 22, and the light-emitting element D in the display panel. Corresponding relationship between other second sensors 22 in the first photosensitive unit 20, the second photosensitive channel 202 and the light-emitting elements D in the transition region A12 may refer to FIG. 8.

Referring to FIG. 8, in an optional implementation manner of the present disclosure, the second photosensitive channel 202 may include the first filter film 51. The first light filter film 51 may include a red color resist R, a green color resist G and a blue color resist B. Same second photosensitive channel 202 may correspond to a color resist. The red color resist R, the green color resist G and the blue color resist B may be on the side of the light-emitting element D facing toward the light-exiting surface of the display panel.

When the second photosensitive channel 202 is configured to transmit light of a single color, the first filter film 51 may be disposed in the second photosensitive channel 202. For example, when the second photosensitive channel 202 is configured to transmit green light to corresponding second sensor 22, the green color resist G may be disposed in the second photosensitive channel 202; when the second photosensitive channel 202 is configured to transmit red light to corresponding second sensor 22, the red color resist R may be disposed in the second photosensitive channel 202; and when the second photosensitive channel 202 is configured to transmit blue light to corresponding second sensor 22, the green color resist G may be disposed in the second photosensitive channel 202. The process of forming the second photosensitive channel 202 filled with the color resist may be performed simultaneously with the process of disposing the color resist in the color filter layer 90. That is, there is no need to introduce a separate formation process for the second photosensitive channel 202. The formation process of the color filter layer 90 may be reused to complete the formation of the second photosensitive channel 202, thereby being beneficial for simplifying the formation process when the second photosensitive channel 202 is formed into the display panel and improving the formation efficiency.

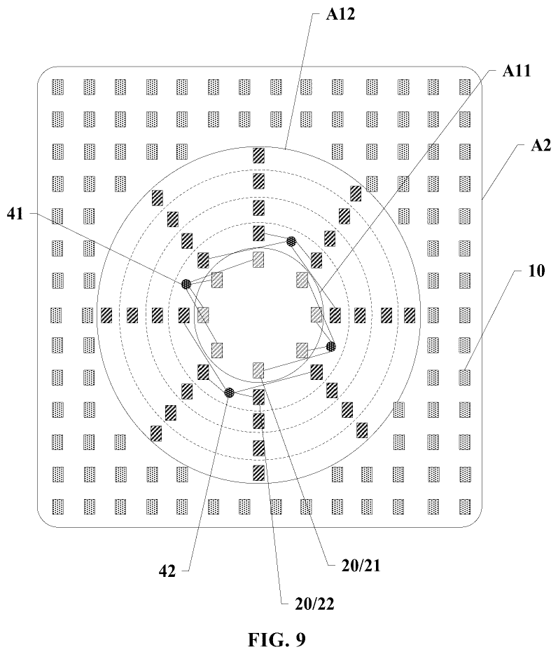

FIG. 9 illustrates another local enlarged view of the first display region A1 and a part of the second display region A2 surrounding the first display region A1 in FIG. 1. In addition to the sensors, a part of the driving circuits connected to the sensors may be shown in one embodiment. In an optional implementation manner of the present disclosure, the first photosensitive unit 20 may further include the second driving circuit 42 connected to the second sensor 22; and the second driving circuit 42 may be at the transition region A12. Same second driving circuit 42 may be connected to a quantity M of second sensors 22, where M≥4. The color resists corresponding to the quantity M of second sensors 22 connected to same second driving circuit 42 may have same color.

When the second sensor 22 and the second photosensitive channel 202 are disposed in the transition region A12, the second sensor 22 may be connected to the second driving circuit 42, and the signal sensed by the second sensor 22 may be transmitted to the second driving circuit 42 for processing. When the second driving circuit 42 is disposed in the transition region A12, the second driving circuit 42 may not occupy the space of the first region A11, which may be beneficial for ensuring the transmittance of the first region A11. When same second driving circuit 42 is connected to at least four second sensors 22, the brightness signals corresponding to same color light sensed by all second sensors 22 connected to same second driving circuit 42 may be transmitted to the second driving circuit 42, and the signals may be read through same second driving circuit 42, thereby realizing the identification of the full-band light brightness in the ambient light. Such design manner may be beneficial for reducing the quantity of second driving circuits 42 actually included in the display panel and preventing a large quantity of second driving circuits 42 from affecting the PPI of the display product.

It should be noted that the quantity and arrangement of the second sensors 22 in one embodiment shown in FIG. 9 may be only exemplary and may not represent the quantity of second sensors 22 actually included in the transition region A12. FIG. 9 only illustrates a connection scenario between the second sensors 22 and the second driving circuit 42. The other connection scenarios between the second sensors 22 and the second driving circuit 42 may refer to above description, which may not be described in detail herein. The second sensor 22 mentioned in embodiments of the present disclosure may be an ambient light sensor or a color temperature sensor.

In one embodiment shown in FIG. 9, in the transition region A12, the color resists corresponding to the second sensors 22 at same annular region may have same color. For example, along the direction from the first region A11 to the transition region A12, the second sensors 22 at the first circle may be configured to sense red light, the second sensors 22 at the second circle may be configured to sense green light, and the second sensors 22 at the third circle may be configured to sense blue light. It should be noted that in FIG. 9, the second sensors 22 that sense red light, green light and blue light may be arranged in three circles, which may be only taken as an example for illustration. However, the quantity of second sensors 22 actually included in each circle may not be limited, and the quantity of circles of second sensors 22 that sense light of same color may also not be limited.

It should also be noted that the quantity of second sensors 22 that sense light of different colors in the transition region A12 may not be limited in one embodiment. The quantity of the second sensors 22 that sense red light, the quantity of the second sensors 22 that senses green light, and the quantity of the second sensors 22 that sense blue light may be same or may be configured to be different according to needs. For example, the quantity of the second sensors 22 may be designed differently according to different absorption rates of the second sensors 22 for three colors of red, green and blue light. When the absorption rate of light of a certain color (assumed to be blue) is relatively high, the quantity of second sensors 22 that sense blue light may be designed to be relatively low, which is less than the quantity of second sensors 22 that sense each of other two types of light. When the quantity of second sensors 22 that sense blue light is relatively low, the quantity of blue color resists corresponding to the second sensors 22 may also be relatively low. When the absorption rate of light of a certain color (assumed to be red or green) is relatively low, the second sensors 22 for sensing red and green light may be disposed as high as possible, which may be beneficial for improving light sensing precision of the first photosensitive unit 20. When the quantity of second sensors 22 that sense red and green light is relatively high, the quantity of corresponding red color resists R and green color resists G may also be relatively high.

Referring to FIG. 8, in an optional implementation manner of the present disclosure, the first photosensitive unit 20 may further include the third sensor 23 and the third photosensitive channel 203; along the direction perpendicular to the plane of the display panel, the third photosensitive channel 203 may be overlapped with the third sensor 23; the third photosensitive channel 203 may be on the side of the third sensor 23 facing toward the light-exiting surface of the display panel; the third photosensitive channel 203 may be configured to transmit other light except infrared light and near-infrared light; and the third sensor 23 and the third photosensitive channel 203 may be at the transition region A12.

For example, in addition to including the first photosensitive channel 201 for transmitting the full-band light and the second photosensitive channel 202 for transmitting single-color light, the first photosensitive unit 20 may further include the third photosensitive channel 203 for transmitting other light except infrared light and near-infrared light. Correspondingly, the third sensor 23 may be configured to sense other light transmitted by the third photosensitive channel 203 except infrared light and near-infrared light. In such way, the first photosensitive unit 20 may include photosensitive channels for transmitting a variety of different light, such as the first photosensitive channel 201 for transmitting the full-band light, the second photosensitive channel 202 for transmitting red light, the second photosensitive channel 202 for transmitting green light, the second photosensitive channel 202 for transmitting blue light, and the third photosensitive channel 203 for transmitting other light except infrared light and near-infrared light. In such way, the first photosensitive unit 20 may sense ambient light with high precision.

Optionally, the structures of the sensors corresponding to different photosensitive channels may be same, and the structures of the driving circuits corresponding to the sensors may also be same. The only difference is that the light sensed by the sensors may be different, that is, the filter films corresponding to the second sensors 22 may be different, or no filter film may be disposed. For example, the second sensor 22 that senses red light may correspond to the red color resist R, the second sensor 22 that senses green light may correspond to the green color resist G, and the second sensor 22 that senses blue light may correspond to the blue color resist B. No filter film may be directly disposed above the first sensor 21 that senses the full-band light, and the third sensor 23 that senses other light except infrared light and near-infrared light may correspond to an infrared cut-off film 521. In such way, when the sensors and the driving circuits corresponding to the sensors are integrated into the display panel, there is no need to perform different design for the sensors and corresponding driving circuits that sense different lights, thereby being beneficial for simplifying overall formation process of the display panel.

Referring to FIG. 8, in an optional implementation manner of the present disclosure, the third photosensitive channel 203 may include the second filter film 52; the second filter film 52 may include the infrared cut-off film 521. The display panel may include a plurality of light-emitting elements D arranged in the first display region A1 and the second display region A2. Along the direction perpendicular to the plane of the display panel, the third photosensitive channel 203 may not be overlapped with the light-emitting elements D. The infrared cut-off film 521 may be on the side of the light-emitting element D facing toward the light-exiting surface of the display panel.

As mentioned in previous embodiments, in order to reduce the reflectivity of the OLED display panel, the color film layer 90 may be disposed on the side of the light-emitting element D facing toward the display panel. The color filter layer 90 may include the color resist and the light-blocking matrix. When the first photosensitive unit 20 is disposed with the third photosensitive channel 203, the third photosensitive channel 203 may be disposed on the color filter layer 90. For example, a hole structure (for passing light) corresponding to the third sensor 23 may be formed on the color filter layer 90, and the infrared cut-off film 521 may be disposed in the hole structure. In such way, the light emitted to the third sensor 23 through the infrared cut-off film 521 may mainly include visible light, and the third sensor 23 may sense visible light, thereby increasing the types of light that the first photosensitive unit 20 can identify. When the third photosensitive channel 203 and the third sensor 23 are disposed, the third photosensitive channel 203 may be overlapped with the third sensor 23 along the direction perpendicular to the plane of the display panel, and the third photosensitive channel 203 and the light-emitting element D may be configured to be not overlapped with each other, which may be beneficial for avoiding the light emitted from the light-emitting element D from entering the photosensitive channel to cause false recognition by the third sensor 23 and avoiding the problem of display color shift caused by the light emitted from the light-emitting element D from the third photosensitive channel 203 to the light-exiting surface of the display panel.

In some other embodiments of the present disclosure, according to actual application requirement, the second filter film 52 may also include a UV cut-off film to block UV light and allow other light except UV light to pass through, thereby achieving more accurate ambient light recognition.

Referring to FIG. 8, in an optional implementation manner of the present disclosure, the fingerprint recognition unit 10 may include a fingerprint recognition sensor 11 and a fingerprint recognition channel 101; the fingerprint recognition channel 101 may be on the side of the fingerprint recognition sensor 11 facing toward the light-exiting surface of the display panel; and the fingerprint recognition channel 101 may include the infrared cut-off film 521.

The fingerprint recognition unit 10 may be disposed in the second display region A2. Optionally, the fingerprint recognition units 10 may be evenly arranged in the second display region A2. The quantity of the fingerprint recognition unit 10 may be configured to be consistent with the quantity of sub-pixels in the second display region A2. Along the direction perpendicular to the plane of the display panel, the fingerprint recognition channel 101 may be overlapped with the fingerprint recognition sensor 11. The fingerprint recognition channel 101 may include the infrared cut-off film 521. During the fingerprint recognition process, the visible light reflected by a touch main body may be transmitted to the fingerprint recognition sensor 11 through the fingerprint recognition channel 101. When the fingerprint recognition channel 101 includes the infrared cut-off film 521, the filter film in the fingerprint recognition channel 101 and the third photosensitive channel 203 corresponding to the first photosensitive unit 20 may be formed using a same process. Therefore, there is no need to introduce different formation processes for the fingerprint recognition channel 101 and the third photosensitive channel 203, which may be beneficial for simplifying overall formation process of the display panel and improving the formation efficiency.

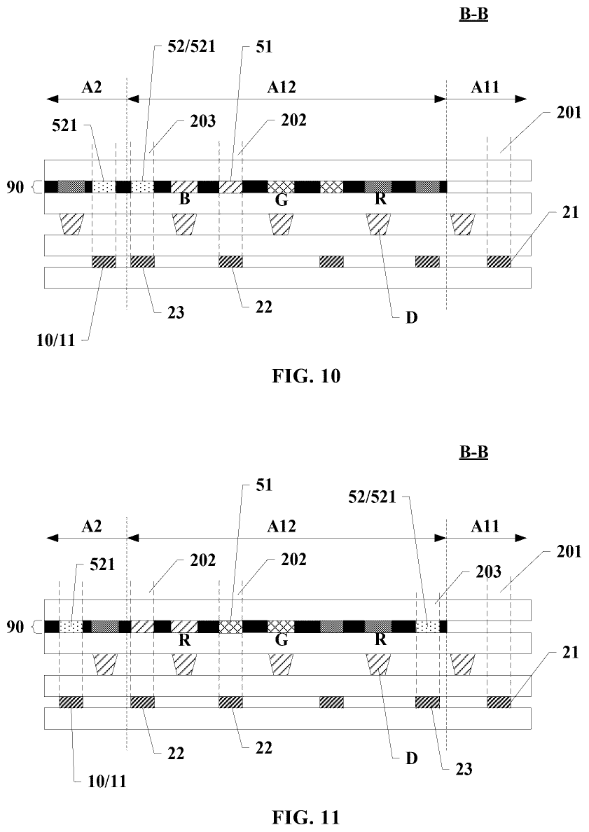

FIG. 10 illustrates another film layer schematic along the BB direction in FIG. 4. The difference between FIG. 10 and FIG. 8 is different designs of the interface between the transition region A12 and the second display region A2. Referring to FIG. 10, in an optional implementation manner of the present disclosure, the third sensor 23 may be between the second sensor 22 and the second display region A2 along the direction in parallel with the light-exiting surface of the display panel; along the direction in parallel with the plane of the display panel, no light-emitting element D may be disposed between the third photosensitive channel 203 located at the edge of the transition region A12 and the fingerprint recognition channel 101 located near the edge of the transition region A12 of the second display region A2; and the infrared cut-off film 521 of the fingerprint recognition channel 101 and the infrared cut-off film 521 of the third photosensitive channel 203 may be arranged in a same layer.

When the fingerprint recognition sensor 11, the third sensor 23 for identifying visible light, and the second sensor 22 for identifying single-color light are all disposed in the display panel, in embodiments of the present disclosure, the fingerprint recognition sensor 11 may be disposed in the second display region A2 with a relatively large area, and the second sensor 22 and the third sensor 23 may be disposed in the transition region A12 in the first display region A1 with a relatively small area. The arrangement manner of the photosensitive channels corresponding to above sensors in the transition region A12 and the second display region A2 may be configured as that the third photosensitive channel 203 corresponding to the fingerprint recognition sensor 11 and the third photosensitive channel 203 corresponding to the third sensor 23 may be configured to be adjacent to each other. That is, the third photosensitive channel 203 may be disposed at the edge position of the transition region A12, and the second photosensitive channel 202 may be disposed at the non-edge position of the transition region A12. Meanwhile, in one embodiment, it further limits that along the direction in parallel with the plane of the display panel, the light-emitting element D may not be disposed between the fingerprint recognition channel 101 adjacent to the transition region A12 in the second display region A2 and the third photosensitive channel 203 adjacent to the second display region A2 in the transition region A12. In such way, the fingerprint recognition channel 101 and the third photosensitive channel 203 mentioned above may be in an adjacent relationship, and no color resist corresponding to the light-emitting element D may be disposed between the fingerprint recognition channel 101 and the third photosensitive channel 203. Moreover, the infrared cut-off film 521 may be disposed in above-mentioned two channels. Such adjacent arrangement manner may enable the transition of the optical visual effect in above regions, which may be beneficial for preventing sudden change in the visual effect.

FIG. 11 illustrates another film layer schematic along the BB direction in FIG. 4. The difference between FIGS. 8 and 10 is that the interface position between the transition region A12 and the second display region A2 may be designed differently. Referring to FIG. 11, in an optional implementation manner of the present disclosure, the fingerprint recognition unit 10 may include the fingerprint recognition sensor 11 and the fingerprint recognition channel 101; the fingerprint recognition channel 101 may be on the side of the fingerprint recognition sensor 11 facing toward the light-exiting surface of the display panel; along the direction in parallel with the light-exiting surface of the display panel, the second sensor 22 may be between the third sensor 23 and the second display region A2; the fingerprint recognition channel 101 may be not disposed between the second sensor 22 at the edge of the transition region A12 and the light-emitting element D which is adjacent to the edge of the second display region A2 and in the transition region A12; and the fingerprint recognition channel 101 may include the infrared cut-off film 521.

When the fingerprint recognition sensor 11, the third sensor 23 for identifying visible light, and the second sensor 22 for identifying single-color light are all disposed in the display panel, in embodiments of the present disclosure, the fingerprint recognition sensor 11 may be disposed in the second display region A2 with a relatively large area; and the second sensor 22 and the third sensor 23 may be disposed in the transition region A12 in the first display region A1 with a relatively small area. The arrangement manner of the photosensitive channels corresponding to above sensors in the transition region A12 and the second display region A2 may be configured as that along the direction in parallel with the light-exiting surface of the display panel, the second photosensitive channel 202 corresponding to the second sensor 22 may be adjacent to the light-emitting element D in the second display region A2; in the transition region A12, the second photosensitive channel 202 may be disposed to be adjacent to the second display region A2; and in the second display region A2, the filter film corresponding to the light-emitting element D, not the fingerprint recognition channel 101, may be adjacent to the second photosensitive channel 202 in the transition region A12. In such way, in the interface region of the transition region A12 and the second display region A2, the filter film corresponding to the light-emitting element D in the second display region A2 may be adjacent to the second photosensitive channel 202 of the transition region A12. The second photosensitive channel 202 may be also disposed with the filter film. Therefore, similar to the filter film corresponding to the light-emitting element D, adjacent arrangement manner of the light-emitting element D and the second photosensitive channel 202 may enable the transition of the optical visual effect in the transition region A12 and the second display region A2, which may be beneficial for preventing sudden change in the visual effect.

It should be noted that in embodiments of the present disclosure, the color of the filter film corresponding to the light-emitting element D adjacent to the transition region A12 and in the second display region A2 may not be limited; and the color of the filter film in the second photosensitive channel 202 adjacent to the second display region A2 and in the transition region A12 may not be limited. The colors of above two filter films may be same or different.

Referring to FIG. 5, in an optional implementation manner of the present disclosure, the photosensitive unit (including the fingerprint recognition unit 10 and the first photosensitive unit 20) may include the photosensitive channel; both the first display region A1 and the second display region A2 may include a plurality of light-emitting elements D; along the direction perpendicular to the light-exiting surface of the display panel, the photosensitive channel and the light-emitting element D may be not overlapped with each other; and the minimum separation distance between the orthographic projection of the photosensitive channel on the plane of the display panel and the orthographic projection of the light-emitting element D, which is adjacent to the photosensitive channel, on the plane of the display panel is D0, where 3 μm≤D0≤10 μm.

The photosensitive unit in above-mentioned embodiments may include the fingerprint recognition unit 10 and the first photosensitive unit 20. When the first photosensitive unit 20 is disposed in the first display region A1 and the fingerprint recognition unit 10 is disposed in the second display region A2, the first photosensitive unit 20 and the fingerprint recognition unit 10 may spatially avoid the light-emitting element D in the display region. Meanwhile, along the direction in parallel with the light-exiting surface of the display panel, a certain distance may be between the photosensitive channel in the photosensitive unit and the light-emitting element D adjacent to the photosensitive channel. When the distance between the photosensitive channel in the photosensitive unit and the light-emitting element D adjacent to the photosensitive channel is excessively small, for example, less than 3 μm, the light emitted from the light-emitting element D may be transmitted to the photosensitive channel, which may affect the accuracy of light recognition by the sensor in the photosensitive unit. If the distance between emitted by is excessively large, for example, greater than 10 μm, the space occupied by the light-emitting element D and the photosensitive unit on the display panel may become larger, which may result in the PPI reduction of the display panel. Therefore, in embodiments of the present disclosure, the minimum distance between the photosensitive channel and the light-emitting element D adjacent to the photosensitive channel along the direction in parallel with the plane of the display panel may be configured to be 3 μm≤D0≤10 μm, which may not only prevent the light emitted from the light-emitting element D from affecting the recognition accuracy of the sensor in the photosensitive unit, but also be beneficial for ensuring the recognition accuracy of the photosensitive unit and the PPI of the display panel.

In an optional implementation manner of the present disclosure, in the first display region A1, the quantity of sensors corresponding to the first photosensitive units 20 may be less than the quantity of light-emitting elements D; and in the second display region A2, the quantity of sensors corresponding to the fingerprint recognition units 10 may be equal to the quantity of light-emitting elements D.

The first photosensitive unit 20 above-mentioned embodiments of the present disclosure may be configured to sense the ambient light and adjust the display brightness of the display panel according to the brightness of the ambient light. When the first photosensitive unit 20 is disposed in the display panel, only a smaller quantity of photosensitive units (compared to the light-emitting elements D in the first display region A1) may be needed to realize the ambient light recognition function. Therefore, there is no need to dispose same quantity of photosensitive units as the light-emitting elements D in the first display region A1, which may reduce the space occupied by the photosensitive units in the first display region A1 and ensure the transmittance of the first display region A1. In the second display region A2, the quantity of fingerprint recognition units 10 may be configured to be equal to the quantity of light-emitting elements D, and one fingerprint recognition unit 10 may be disposed next to each light-emitting element D, which may be beneficial for improving the arrangement uniformity of the fingerprint recognition units 10 in the second display region A2 and ensuring the consistency of the fingerprint recognition effect in different regions of the second display region A2.

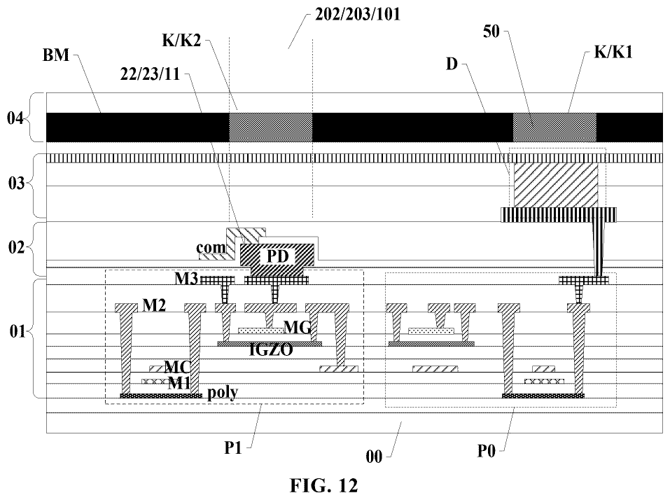

FIG. 12 illustrates a detailed film layer schematic of the display panel according to various embodiments of the present disclosure. In one embodiment, a driving layer 01, a light-emitting layer 03 and the like on the display panel may be described in detail. Referring to FIGS. 5 and 12, in an optional implementation manner of the present disclosure, the display panel may include a substrate 00, and the driving layer 01, a sensing layer 02, a light-emitting layer 03 and a filter layer 04 which are disposed on the side of the substrate 00; the sensing layer 02 may be between the driving layer 01 and the light-emitting layer 03; the driving layer 01 may be on the side of the sensing layer 02 facing toward the substrate; the filter layer 04 may be on the side of the light-emitting layer 03 away from the substrate; the light-emitting layer 03 may include the light-emitting element D; the filter layer 04 may include a light-blocking matrix BM and a plurality of openings K defined by the light-blocking matrix BM; the openings K may include the first opening K1 and the second opening K2; along the direction perpendicular to the substrate 00, the first opening K1 may be overlapped with the light-emitting element D; the photosensitive unit (e.g., the fingerprint recognition unit or the first photosensitive unit in above-mentioned embodiments) may include multiple sensors 22/23/11 and photosensitive channels 202/203/101; along the direction perpendicular to the substrate, the second opening K2 may be overlapped with the sensor 22/23/11; at least a part of the photosensitive channels 202/203/101 may include the filter film 50; the filter film 50 may be at the second opening K2; and the filter film 50 may be also disposed in at least a part of the first openings K1.

In one embodiment, when the display panel provided by embodiments of the present disclosure is the OLED display panel, the solution that the filter layer 04 is disposed on the side of the light-emitting element D of the OLED display panel facing toward the light-exiting surface of the display panel may be used. The light-blocking matrix BM in the filter layer 04 has the function of absorbing light. When ambient light shines on the display panel, the light reaching the light-blocking matrix may be absorbed by the light-blocking matrix BM, which may prevent such part of the light from being reflected to affect the user experience, thereby improving anti-reflective performance of the display panel. The thickness of the filter layer 04 may be configured to be relatively small. The manner of disposing the filter layer 04 into the display panel to improve anti-reflective performance of the display panel may be beneficial for controlling overall thickness of the display panel and satisfying the requirement for thin display products.

The first opening K1 and the second opening K2 in the filter layer 04 may be both surrounded by the light-blocking matrix BM. The first opening K1 in the filter layer 04 may correspond to the light-emitting element D and may be configured to direct the light emitted from the light-emitting element D to the light-exiting surface of the display panel. The second opening K2 in the filter layer 04 may correspond to the sensor 22/23/11 and may be regarded as a part of the photosensitive channel corresponding to partial photosensitive unit. In actual formation process, the first opening K1 and the second opening K2 may be formed in a same process, and there is no need to use different formation processes for the first opening K1 and the second opening K2, which may be beneficial for simplify the formation process of the display panel when the fingerprint recognition unit 10 and the first photosensitive unit 20 are disposed in the display panel, thereby being beneficial for improving the formation efficiency.

In addition, in the transition region A12 between the second display region A2 and the first display region A1, the first opening K1 and the second opening K2 may be both filled with the filter films. These filter films may be formed using a same process. A part of the filter film in the second opening K2 and a part of the filter film in the first opening K1 may be formed using a same process, thereby simplifying overall formation process. The film layer structures corresponding to the light-emitting element and the photosensitive unit in the transition region and the second display region may refer to FIG. 12. In the first region, the light-blocking matrix and filter film corresponding to the filter layer 04 may be removed to increase the transmittance of the first region.

Optionally, the driving layer 01 may be disposed with the driving circuits including the pixel driving circuit P0 for driving the light-emitting element and the photosensitive driving circuit P1 for driving the photosensitive unit. The pixel driving circuit P0 may be configured to be connected to the light-emitting element D and drive the light-emitting element D to emit light. The photosensitive driving circuit P1 may be configured to be connected to the first photosensitive unit 20 or the sensors 22/23/11 in the fingerprint identification unit 10 and may be configured to receive sensing signals. Optionally, the sensors 22/23/11 in the fingerprint identification unit 10 and the first photosensitive unit 20 may be photodiodes (PD). The photodiode may use a film structure in the existing technology, including a P-type semiconductor, an N-type semiconductor and a photosensitive layer. The P-type semiconductor and the N-type semiconductor may form a PN junction. When there is no light, the photodiode PD may be in a forward biased state and the current may be extremely small. When light irradiates the photosensitive layer of the photodiode, the photons may excite electrons and holes in the semiconductor of the photodiode to forming a potential difference in the PN junction region and form a current. The P-type semiconductor and N-type semiconductor in the sensor may be respectively connected to the photosensitive driving circuit P1 and the common voltage signal line com. The current generated in the sensor may be outputted to the photosensitive driving circuit P1, thereby realizing the light sensing function. Optionally, the driving layer 01 may include oxide thin film transistors and amorphous silicon thin film transistors. The transistor connected to the photosensitive diode PD in the photosensitive driving circuit P1 may be an oxide thin film transistor, and the transistor connected to the light emitting element D in the pixel driving circuit P0 may be an amorphous silicon thin film transistor. It should be noted that FIG. 12 only illustrates a connection relationship between the transistors in the driving layer 01, the photodiode PD and the light-emitting element D, which may not limit the types of transistors actually connected to the photodiode PD and the light-emitting element D. Specific structure of the driving layer 01 is described below using FIG. 12 as an example. Optionally, the driving layer 01 may include an active layer Poly, a first metal layer M1, a capacitive metal layer MC, an oxide layer IGZO, the gate metal layer MG, the second metal layer M2 and the third metal layer M3 which are disposed on the substrate 00. The first metal layer M1 may be configured as, for example, a gate metal layer of the amorphous silicon thin film transistor. The capacitor metal layer MC may be configured to form a capacitor structure with the first metal layer M1. The source electrode and the drain electrode of the amorphous silicon thin film transistor in the display panel may be in the second metal layer M2. The active layer poly may include a source-electrode region and a drain-electrode region. The source-electrode region and the drain-electrode region may be formed by doping N-type impurity ions or P-type impurity ions. The source electrode of the amorphous silicon thin film transistor may be electrically connected to the source-electrode region of the semiconductor layer poly through a contact hole; and the drain electrode of the amorphous silicon thin film transistor may be electrically connected to the drain-electrode region of the active layer poly through a contact hole. The gate metal layer MG may be configured as the gate electrode of the oxide thin film transistor. The source electrode and the drain electrode of the oxide thin film transistor may also be in the second metal layer M2 and may be electrically connected to the oxide layer through via a hole. The third metal layer M3 may be regarded as a wiring layer and configured to electrically connect a corresponding transistor to the sensor or light-emitting element D. It should be noted that the film structure in FIG. 12 may be only exemplary and may not limit actual film structure of the display panel.

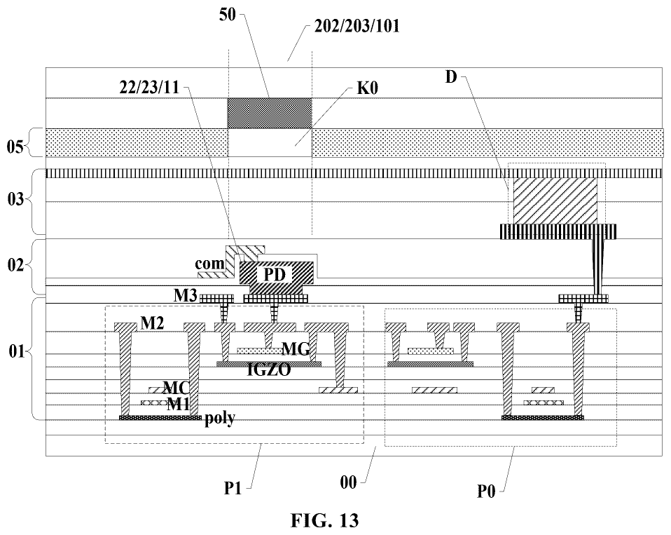

In above-mentioned embodiments, the solution of disposing the filter layer 04 in the display panel to reduce the reflectivity of the display product may be taken as an example for illustration. In addition to such solution, a polarizer 05 may also be disposed on the side of the light-emitting element D facing toward the light-exiting surface of the display panel to reduce the reflectivity of the display product. For example, referring to FIG. 13, FIG. 13 illustrates another detailed film layer schematic of the display panel according to various embodiments of the present disclosure.

Referring FIGS. 5 and 13, in an optional implementation manner of the present disclosure, the display panel may include the substrate 00, and the driving layer 01, the sensing layer 02, the light-emitting layer 03 and the polarizer 05 which are disposed on one side of the substrate 00; the sensing layer 02 may be between the driving layer 01 and the light-emitting layer 03; the driving layer 01 may be on the side of the sensing layer 02 facing toward the substrate; the polarizer 05 may be on the side of the light-emitting layer 03 facing toward away from the substrate; the sensors 22/23/11 in the fingerprint recognition unit 10 and the first photosensitive unit 20 may be all in the sensing layer 02; the polarizer 05 may include a plurality of hole structures K0; the photosensitive unit may include photosensitive channels 202/203/101; along the direction perpendicular to the plane of the display panel, the hole structures K0 may be overlapped with the photosensitive channels 202/203/101; and at least a part of the photosensitive channels may include the filter film 50 which is on the side of the polarizer 05 facing toward away from the substrate.

Referring to FIG. 13, when the polarizer 05 is disposed on the side of the light-emitting element D facing toward the light-exiting surface of the display panel, the reflectivity of the display product may be reduced using the polarizer 05. When the polarizer 05 is disposed, the polarizer 05 may be disposed with the hole structure K0; and the photosensitive channels 202/203/101 in the fingerprint recognition unit 10 and the first photosensitive unit 20 may be disposed corresponding to the hole structures K0. In such way, external light may be transmitted to corresponding sensor through the hole structure K0 to realize the fingerprint recognition function or ambient light sensing function. The film layer structure corresponding to the light-emitting element and the photosensitive unit in the transition region and the second display region may refer to FIG. 13. In the first region, the polarizer and filter film may be removed to increase the transmittance of the first region.

It should be noted that for the display panel with disposed polarizer 05, the structure of the driving layer 01 and the connection relationship between the driving layer 01, the light-emitting element D and the sensor may refer to the solution corresponding to one embodiment shown in FIG. 12, which may not be described in detail herein.

For the first region A11 in the display panel, due to relatively high transmittance requirement, the filter layer 04 disposed in the display panel as shown in FIG. 12 or the polarizer 05 disposed in the display panel as shown in FIG. 13 may be removed in the first region A11, which may increase the amount of light in the first region and improve the image-capturing effect.

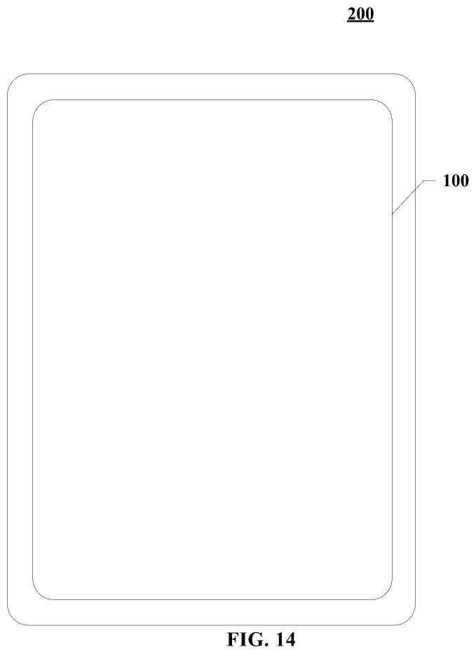

Based on same inventive concept, the present disclosure also provides a display apparatus. FIG. 14 illustrates a structural schematic of a display apparatus according to various embodiments of the present disclosure. Referring to FIG. 14, a display apparatus 200 may include the display panel 100 in any of above-mentioned embodiments.

The display apparatus 200 provided by embodiments of the present disclosure may be a touch screen, a mobile phone, a tablet computer, a notebook computer, an electronic paper book or a television, or any other electronic device with a display function. The display apparatus 200 provided by embodiments of the present disclosure may have the beneficial effects of the display panel 100 provided by embodiments of the present disclosure, which may refer to specific description of the display panel 100 in above-mentioned embodiments and may not be described in detail herein.

It should be understood that FIG. 14 only illustrates one shape of the display apparatus 200 by taking a rounded rectangular structure as an example. In some other embodiments of the present disclosure, the display apparatus 200 may also be embodied as a rectangle, a circle, an oval or any other feasible shape, which may not be limited in the present disclosure.

It may be seen from above-mentioned embodiments that the display panel and the display apparatus provided by the present disclosure may at least achieve the following beneficial effects.

In the display panel and display apparatus provided by the present disclosure, when the fingerprint recognition unit and the first photosensitive unit are disposed in the display panel, the fingerprint recognition unit may be disposed in the second display region with a relatively large area; the first photosensitive unit may be disposed in the first display region with a relatively small region; and the fingerprint recognition unit and the first photosensitive unit may not be overlapped in the disposing space, thereby being beneficial for avoiding the problem of reduced PPI caused by space squeezed when the fingerprint recognition unit and the first photosensitive unit are overlapped in the disposing space. Therefore, while realizing fingerprint recognition and ambient light sensing simultaneously, it is also beneficial for improving the PPI of the display panel. In addition, when the fingerprint recognition unit is disposed in the first display region in embodiments of the present disclosure, the area of the first display region may be relatively large, which may be beneficial for realizing full-screen fingerprint recognition and meeting full-screen fingerprint recognition need of users. Since the first photosensitive unit only needs a relatively small region to install corresponding sensors to realize the ambient light sensing function, the first photosensitive unit may be disposed in the first display region to meet the region size requirement for ambient light sensing without being overlapped with the fingerprint recognition unit in the second display region.

Although some embodiments of the present disclosure have been described in detail through various embodiments, those skilled in the art should understand that above-mentioned embodiments may be for illustration only and may not be intended to limit the scope of the present disclosure. Those skilled in the art should understood that modifications may be made to above-mentioned embodiments without departing from the scope and spirit of the present disclosure. The scope of the present disclosure may be defined by the appended claims.

What is claimed is:

1. A display panel, comprising:
a first display region and a second display region, wherein the second display region at least partially surrounds the first display region, and a transmittance of at least a part of the first display region is greater than a transmittance of the second display region; and
a plurality of photosensitive units, wherein the plurality of photosensitive units includes a plurality of fingerprint recognition units and a plurality of first photosensitive units; the plurality of first photosensitive units is at the first display region; the plurality of fingerprint recognition units is at the second display region; and the plurality of first photosensitive units includes a plurality of color temperature sensors and/or a plurality of ambient light sensors.

2. The display panel according to claim 1, wherein:
the first display region includes a first region and a transition region; the transition region is between the first region and the second display region; and a transmittance of the first region is greater than a transmittance of the transition region;
a first photosensitive unit includes an ambient light sensor containing a first sensor and a first photosensitive channel; along a direction perpendicular to a plane of the display panel, the first photosensitive channel is overlapped with the first sensor; and the first photosensitive channel is on a side of the first sensor facing toward a light-exiting surface of the display panel; and
the first photosensitive channel is configured to transmit full-band light; and the first sensor and the first photosensitive channel are at the first region.

3. The display panel according to claim 2, wherein:
the first photosensitive unit further includes a first driving circuit connected to the first sensor; and the first driving circuit is at the transition region.

4. The display panel according to claim 3, wherein:
a same first driving circuit is connected to a quantity N of first sensors, wherein N≥4.

5. The display panel according to claim 2, wherein:
another first photosensitive unit includes a color temperature sensor containing a second sensor and a second photosensitive channel; along the direction perpendicular to the plane of the display panel, the second photosensitive channel is overlapped with the second sensor; and the second photosensitive channel is on a side of the second sensor facing toward the light-exiting surface of the display panel; and
the second photosensitive channel is configured to transmit red light, green light or blue light; and the second sensor and the second photosensitive channel are at the transition region.

6. The display panel according to claim 5, further including:
a plurality of light-emitting elements disposed in the first display region and the second display region, wherein along the direction perpendicular to the plane of the display panel, the second photosensitive channel is not overlapped with a light-emitting element.

7. The display panel according to claim 6, wherein:
the second photosensitive channel includes a first filter film; the first filter film includes a red color resist, a green color resist and a blue color resist; a same second photosensitive channel corresponds to a color resist of one color; and the red color resist, the green color resist and the blue color resist are on a side of the light-emitting element facing toward the light-exiting surface of the display panel.

8. The display panel according to claim 7, wherein:
the another first photosensitive unit further includes a second driving circuit connected to the second sensor; the second driving circuit is at the transition region; a same second driving circuit is connected to a quantity M of second sensors, wherein M≥4; and color resists corresponding to the quantity M of second sensors connected to the same second driving circuit have a same color.

9. The display panel according to claim 2, wherein:
another first photosensitive unit includes another ambient light sensor containing a third sensor and a third photosensitive channel; along the direction perpendicular to the plane of the display panel, the third photosensitive channel is overlapped with the third sensor; and the third photosensitive channel is on a side of the third sensor facing toward the light-exiting surface of the display panel; and
the third photosensitive channel is configured to transmit light other than infrared light and near-infrared light; and the third sensor and the third photosensitive channel are at the transition zone.

10. The display panel according to claim 9, wherein:
the third photosensitive channel includes a second filter film including an infrared cut-off film;
the display panel includes a plurality of light-emitting elements disposed in the first display region and the second display region; and along the direction perpendicular to the plane of the display panel, the third photosensitive channel is not overlapped with a light-emitting element; and
the infrared cut-off film is on a side of the light-emitting element facing toward the light-exiting surface of the display panel.

11. The display panel according to claim 9, wherein:
the fingerprint recognition unit includes a fingerprint recognition sensor and a fingerprint recognition channel; and the fingerprint recognition channel is on a side of the fingerprint recognition sensor facing toward the light-exiting surface of the display panel; and
the fingerprint identification channel includes an infrared cut-off film.

12. The display panel according to claim 11, wherein:
along a direction in parallel with the light-exiting surface of the display panel, the third sensor is between the second sensor and the second display region; along a direction in parallel with the plane of the display panel, no light-emitting element is disposed between the third photosensitive channel at an edge of the transition region and the fingerprint recognition channel adjacent to the edge of the transition region and at the second display region; and the infrared cut-off film of the fingerprint identification channel is disposed at a same layer as an infrared cut-off film of the third photosensitive channel.

13. The display panel according to claim 9, wherein:
the fingerprint recognition unit includes a fingerprint recognition sensor and a fingerprint recognition channel; and the fingerprint recognition channel is on a side of the fingerprint recognition sensor facing toward the light-exiting surface of the display panel; and
along a direction in parallel with the light-exiting surface of the display panel, the second sensor is between the third sensor and the second display region; no fingerprint recognition channel is disposed between the second sensor at an edge of the transition region and the light-emitting element adjacent to the edge of the transition region and at the second display region; and the fingerprint identification channel includes an infrared cut-off film.

14. The display panel according to claim 1, wherein:
the photosensitive unit includes a photosensitive channel; both the first display region and the second display region include a plurality of light-emitting elements; along a direction perpendicular to a light-exiting surface of the display panel, the photosensitive channel is not overlapped with a light-emitting element; and a minimum separation distance between an orthographic projection of the photosensitive channel on a plane of the display panel and an orthographic projection of the light-emitting element, adjacent to the photosensitive channel, on the plane of the display panel is D0, wherein 3 μm≤D0≤10 μm.

15. The display panel according to claim 1, wherein:
in the first display region, a quantity of sensors corresponding to first photosensitive units is less than a quantity of light-emitting elements; and at the second display region, a quantity of sensors corresponding to fingerprint recognition units is equal to a quantity of light-emitting elements.

16. The display panel according to claim 1, further including:
a substrate, and a driving layer, a sensing layer, a light-emitting layer and a polarizer which are disposed on a side of the substrate, wherein:
the sensing layer is between the driving layer and the light-emitting layer; the driving layer is on a side of the sensing layer facing toward the substrate; and the polarizer is on a side of the light-emitting layer away from the substrate; and
sensors in the plurality of fingerprint recognition units and the plurality of first photosensitive units are all at the sensing layer; the polarizer includes a plurality of hole structures; the plurality of photosensitive units includes a plurality of photosensitive channels, wherein the plurality of photosensitive channels includes a first photosensitive channel, a second photosensitive channel, a third photosensitive channel, and/or a combination thereof; a hole structure is overlapped with a photosensitive channel along a direction perpendicular to a plane of the display panel; at least a part of the plurality of photosensitive channels includes a filter film; and the filter film is on a side of the polarizer away from the substrate.

17. The display panel according to claim 1, further including:
a substrate, and a driving layer, a sensing layer, a light-emitting layer and a filter layer which are disposed on a side of the substrate, wherein:
the sensing layer is between the driving layer and the light-emitting layer; the driving layer is on a side of the sensing layer facing toward the substrate; the filter layer is on a side of the light-emitting layer away from the substrate; and the light-emitting layer includes a light-emitting element; and
the filter layer includes a light-blocking matrix and a plurality of openings defined by the light-blocking matrix; the plurality of openings includes a first opening and a second opening; along a direction perpendicular to the substrate, the first opening is overlapped with the light-emitting element; the plurality of photosensitive units includes a plurality of sensors and a plurality of photosensitive channels; the second opening is overlapped with a sensor along the direction perpendicular to the substrate; at least a part of the plurality of photosensitive channels includes a light filter film; and the light filter film is in the second opening.

18. A display apparatus, comprising:
a display panel, comprising:
a first display region and a second display region, wherein the second display region at least partially surrounds the first display region, and a transmittance of at least a part of the first display region is greater than a transmittance of the second display region; and
a plurality of photosensitive units, wherein the plurality of photosensitive units includes a plurality of fingerprint recognition units and a plurality of first photosensitive units; the plurality of first photosensitive units is at the first display region; the plurality of fingerprint recognition units is at the second display region; and the plurality of first photosensitive units includes a plurality of color temperature sensors and/or a plurality of ambient light sensors.
